(19) United States
(12) Patent Application Publication
(10) Pub. No.: US 2007/0147132 A1
(43) Pub. Date: Jun. 28, 2007

(54) Pixel circuits including boosting capacitors, methods of driving the same, and image sensors including the same

(75) Inventors: Yong-jei Lee, Seongnam-si (KR); Byung-soo Kim, Yongin-si (KR); Jung-chak Ahn, Suwon-si (KR); Jong-eun Park, Seongnam-si (KR); Hyun-suk Kim, Seoul (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/641,884

(22) Filed: Dec. 20, 2006

(30) Foreign Application Priority Data
Dec. 24, 2005 (KR) 10-2005-0129130

(51) Int. Cl. G11C 11/34; G11C 16/06

(52) U.S. Cl. 365/185.23

(57) ABSTRACT

A pixel circuit of an image sensor includes a photodiode that generates photocharges corresponding to light input to the photodiode; a transfer transistor that transfers the photocharges to a floating diffusion node in response to a transfer control signal; a reset transistor that transfers a power voltage to the floating diffusion node in response to a reset control signal; a signal output unit that outputs a voltage signal corresponding to a voltage of the floating diffusion node in response to a select control signal; and one or more boosting capacitors connected between a gate of the transfer transistor and the floating diffusion node. The reset transistor is an enhancement type MOSFET. A method of driving the pixel circuit and an image sensor are also disclosed.

### PRIORITY STATEMENT

This application claims priority from Korean Patent Application No. 10-2005-0129130, filed on Dec. 24, 2005, in the Korean Intellectual Property Office (KIPO), the entire contents of which are incorporated herein by reference.

### BACKGROUND

1. Field

Example embodiments relate to pixel circuits including one or more boosting capacitors, methods of driving the pixel circuits, and image sensors including the pixel circuits. Also, example embodiments relate to pixel circuits including one or more boosting capacitors and/or a reset transistor that may be an enhancement type metal-oxide silicon field-effect transistor (MOSFET).

2. Description of Related Art

Image sensors capture images and output image signals corresponding to the captured images. The image sensors may be used in cellular phones, digital cameras, and so on and may include complimentary metal-oxide silicon (CMOS) image sensors and/or charge coupled device (CCD) image sensors. Typically, the CMOS image sensor may be cheaper than the CCD image sensor and/or the power consumption of the CMOS sensor may be less than that of the CCD image sensor.

FIG. 1 is a circuit diagram of a pixel circuit of a related art CMOS image sensor. The pixel circuit may include a photodiode PD receiving light Lin, a transfer transistor TTr that may receive a transfer control signal TC, a floating diffusion node FDN, a source follower FTr, a select transistor STr that may receive a select control signal SC, an output node Nout, and/or a reset transistor RTr that may receive a reset control signal RC. One terminal of the photodiode PD may be connected to a source of a reference voltage REF (that may be a ground voltage) and one terminal of the reset transistor RTr may be connected to a source of a power voltage VDD. The output node Nout may output a voltage signal Vout corresponding to the light Lin input to the photodiode PD. The pixel circuit may use a depletion type MOSFET as the reset transistor RTr.

FIG. 2 illustrates potential levels of the reference voltage REF, a region of the photodiode PD, a channel region CH_TTr of the transfer transistor TTr, a region of the floating diffusion node FDN, a channel region CH_RTr of the reset transistor RTr, and the power voltage VDD. The potential level of the channel region CH_TTr of the transfer transistor TTr may vary in response to the logic level of the transfer control signal TC and the potential level of the channel region CH_RTr of the reset transistor RTr may vary in response to the logic level of the reset control signal RC, as shown in FIG. 2. In particular, the potential level of the channel region CH_RTr of the reset transistor RTr may become higher than the potential level of the power voltage VDD when the reset transistor RTr is turned on (represented by ON in FIG. 2) because the reset transistor RTr is a depletion type MOSFET.

Photocharges (in a quantity corresponding to the portion indicated by oblique lines in FIG. 2) generated by the photodiode PD may be transferred to the floating diffusion node FDN via the channel region CH_TTr of the transfer transistor TTr when the transfer transistor TTr is turned on (represented by ON in FIG. 2). A rate of transferring the photocharges from the photodiode PD to the floating diffusion node FDN may be proportional to a difference between the potential level of the region of the photodiode PD and the potential level of the region of the floating diffusion node FDN. Furthermore, the photocharge transfer rate may be proportional to the capacity of the floating diffusion node FDN. That is, as a force of the floating diffusion node FDN-that draws the photocharges integrated in the photodiode PD-becomes stronger, the photocharge transfer rate may become higher.

When a significant number of the photocharges generated by the photodiode PD are not transferred to the floating diffusion node FDN, but remain in the photodiode PD because of a low photocharge transfer rate, it may be difficult for an image sensor including the photodiode PD to output a correct image signal. When a display device receives an image signal from the image sensor and displays an image corresponding to the image signal, the photocharges that remain in the photodiode PD may bring about an offset in the image that deteriorates picture quality.

Accordingly, it may be desirable that the photocharge transfer rate be increased so that a significant number of the photocharges do not remain in the photodiode PD.

### SUMMARY

Example embodiments may provide pixel circuits including one or more boosting capacitors for improving a photocharge transfer rate, methods of driving the pixel circuits, and image sensors including the pixel circuits.

According to example embodiments, a pixel circuit of an image sensor may include a photodiode, a transfer transistor, a reset transistor, a signal output unit, and/or one or more boosting capacitors. The photodiode may generate photocharges corresponding to light input to the photodiode. The transfer transistor may transfer the photocharges to a floating diffusion node in response to a transfer control signal. The reset transistor may transfer a power voltage to the floating diffusion node in response to a reset control signal. The signal output unit may output a voltage signal corresponding to the voltage of the floating diffusion node in response to a select control signal. The one or more boosting capacitors may be connected between the gate of the transfer transistor and the floating diffusion node. The reset transistor may be an enhancement type MOSFET.

According to example embodiments, an image sensor may include a transfer transistor, a reset transistor, one or more boosting capacitors, a signal output unit, and/or a signal converter. The transfer transistor may connect or disconnect a photodiode and a floating diffusion node to or from each other in response to a transfer control signal. The reset transistor may be an enhancement type MOSFET and may transfer a power voltage to the floating diffusion node in response to a reset control signal. The one or more boosting capacitors may be connected between the gate of the transfer transistor and the floating diffusion node and may boost the voltage of the floating diffusion node to a voltage higher than the power voltage at the instant of time or near the time (referred to in this specification as “a time” or “the time”) when the transfer transistor is turned on. The signal output unit may output a voltage signal corresponding to the voltage of the floating diffusion node in response to a select control signal. The signal converter may receive and sample the voltage signal and may output a digital image signal.

The one or more boosting capacitors may boost the voltage of the floating diffusion node to a voltage higher than the power voltage at the time when the transfer transistor is turned on using charges previously stored in the one or more boosting capacitors. If there is more than one boosting capacitor, the capacitors may be connected in series, parallel, a combination of series and parallel, or in some other way.

If there is only one boosting capacitor, the voltage boost may be determined by the capacitance of the boosting capacitor. If there is more than one boosting capacitor, the voltage boost may be determined by the equivalent capacitance of the more than one boosting capacitor.

At least one of the one or more boosting capacitors may have a metal insulator metal (MIM) structure or a polysilicon insulator polysilicon (PIP) structure.

The signal output unit may include a source follower outputting a voltage signal corresponding to the voltage of the floating diffusion node and/or a select transistor transferring the voltage signal output from the source follower to an output node of the pixel circuit in response to the select control signal.

The transfer transistor, the reset transistor, the source follower, and/or the select transistor may be N-type MOSFETs.

The signal converter may compare a voltage signal corresponding to the potential level of the reset state to a voltage signal corresponding to the image voltage and may output the digital image signal in response to the comparison result. The comparison result may be obtained by processing the voltage signal corresponding to the potential level of the reset state and the voltage signal corresponding to the image voltage using correlated double sampling (CDS).

The image sensor may be a CMOS image sensor.

According to example embodiments, a method of driving a pixel circuit may include a transfer transistor connecting or disconnecting a photodiode and a floating diffusion node to or from each other, a reset transistor—that may be an enhancement type MOSFET—transferring a power voltage to the floating diffusion node, a signal output unit outputting a voltage signal corresponding to the voltage of the floating diffusion node, and/or one or more boosting capacitors connected between the gate of the transfer transistor and the floating diffusion node. The method may include turning on the transfer transistor and the reset transistor to maintain the photodiode in an initialization state during a shutter operation period (whether the shutter operation period is predetermined or not); turning off the transfer transistor and turning on the reset transistor such that the floating diffusion node becomes a reset state; permitting the signal output unit to output a voltage signal corresponding to the voltage of the floating diffusion node in the reset state; turning off the reset transistor and turning on the transfer transistor so that the voltage of the floating diffusion node becomes an image voltage corresponding to light input to the photodiode; and/or permitting the signal output unit to output a voltage signal corresponding to the image voltage of the floating diffusion node.

In the turning on of the transfer transistor and the reset transistor to maintain the photodiode in an initialization state during a shutter operation period, the shutter operation period may be controlled in consideration of the intensity of light input to the photodiode and/or a saturation level of the photodiode.

According to example embodiments, the one or more boosting capacitor may boost the voltage of the floating diffusion node to a voltage higher than the power voltage and, thus, a rate of transferring photocharges from the photodiode to the floating diffusion node may be improved. Furthermore, the voltage of the floating diffusion node may be boosted to a voltage higher than the power voltage using the one or more boosting capacitors even during the shutter operation period. Moreover, an offset in an image caused by photocharges remaining in the photodiode may be reduced because the photocharge transfer rate may be improved according to the boosting by the one or more boosting capacitors.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIG. 1 is a circuit diagram of a pixel circuit of a related art CMOS image sensor;

FIG. 2 illustrates potential levels of nodes and channel regions of the pixel circuit of FIG. 1;

FIG. 3 is a circuit diagram of a pixel circuit of an image sensor according to an example embodiment;

FIG. 4 is a diagram for explaining shutter operation of the pixel circuit according to an example embodiment;

FIG. 5 is a timing diagram of control signals for driving the pixel circuit according to an example embodiment;

FIGS. 6A through 6F illustrate potential levels of nodes and channel regions of the pixel circuit of FIG. 3;

FIG. 7 is a circuit diagram of a pixel circuit of an image sensor according to an example embodiment using a depletion type MOSFET as a reset transistor; and

FIGS. 8A and 8B illustrate potential levels of nodes and channel regions of the pixel circuit of FIG. 7 when the control signals of FIG. 5 may be applied to the pixel circuit of FIG. 7.

### DETAILED DESCRIPTION OF EXAMPLE EMBODIMENTS

Example embodiments will now be described more fully with reference to the accompanying drawings. Embodiments, however, may be embodied in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to,” or “coupled to” another component, it may be directly on, connected to, or coupled to the other component or intervening components may be present. In contrast, when a component is referred to as being “directly on,” “directly connected to,” or “directly coupled to” another component, there are no intervening components present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the example embodiments.

Spatially relative terms, such as “beneath,” “below,” “lower,” “above,” “upper,” and the like may be used herein for ease of description to describe the relationship of one component and/or feature to another component and/or feature, or other components and/or features, as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

It will be understood that when used to describe a transistor, the terms “turned on” and “turning on” include the transistor changing from an off state to an on state as well as it remaining in an on state. Similarly, when used to describe a transistor, the terms “turned off” and “turning off” include the transistor changing from an on state to an off state as well as it remaining in an off state.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals refer to the like components throughout.

Example embodiments in which a pixel circuit may be applied to a CMOS image sensor will be discussed.

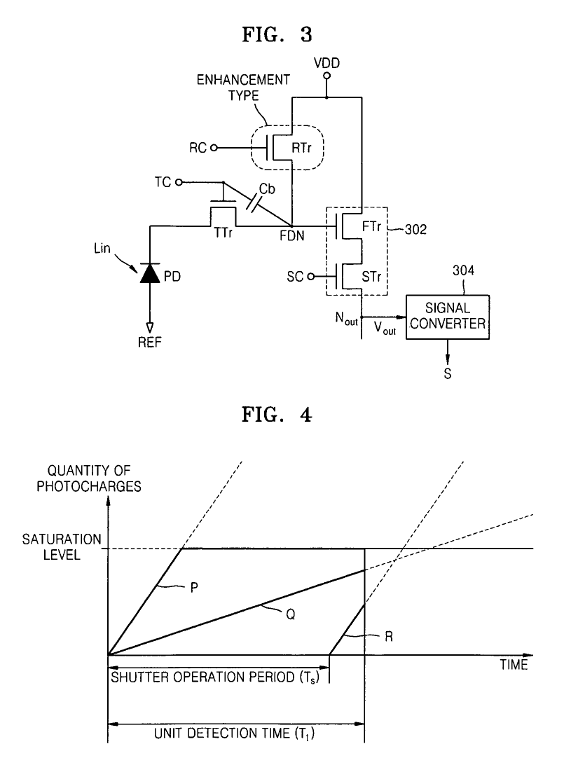

FIG. 3 is a circuit diagram of a pixel circuit of an image sensor according to example embodiments. Referring to FIG. 3, the pixel circuit may include a photodiode PD receiving light Lin, a transfer transistor TTr that may receive a transfer control signal TC, a floating diffusion node FDN, a boosting capacitor Cb, a reset transistor RTr that may receive a reset control signal RC, a signal output unit 302, an output node Nout, and/or a signal converter 304. The signal output unit 302 may include a source follower FTr and/or a select transistor STr that may receive a select control signal SC. One terminal of the photodiode PD may be connected to a source of a reference voltage REF (that may be a ground voltage) and/or one terminal of the reset transistor RTr may be connected to a source of a power voltage VDD. The signal converter 304 may output a digital image signal S corresponding to a voltage signal Vout.

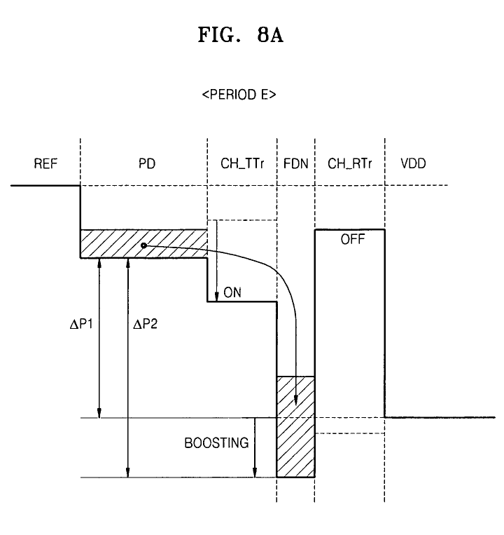

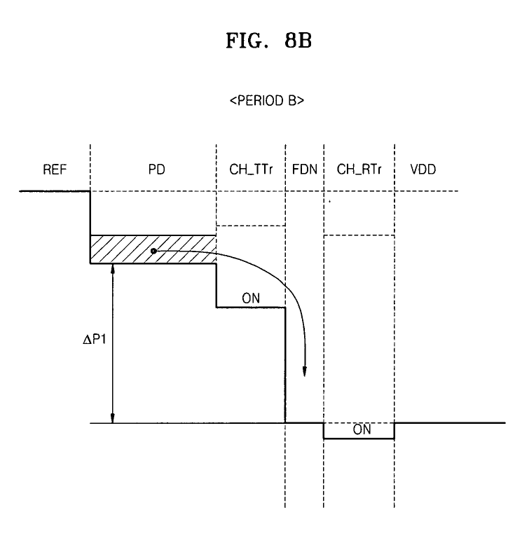

The reset transistor RTr may be an enhancement type MOSFET. The reason why the enhancement type MOSFET may be used as the reset transistor RTr will be explained later with reference to FIG. 8B.

The photodiode PD generates photocharges corresponding to the light Lin input to the photodiode PD. The transfer transistor TTr may transfer at least some of the photocharges generated by the photodiode PD to the floating diffusion node FDN in response to the transfer control signal TC. In FIG. 3, the transfer transistor TTr may be an N-type MOSFET including a gate receiving the transfer control signal TC, a first terminal connected to the floating diffusion node FDN, and/or a second terminal connected to the photodiode PD. The reset transistor RTr may electrically connect the power voltage VDD to the floating diffusion node FDN in response to the reset control signal RC. In FIG. 3, the reset transistor RTr may be an N-type MOSFET including a gate receiving the reset control signal RC, a first terminal connected to the source of the power voltage VDD, and/or a second terminal connected to the floating diffusion node FDN.

When the reset transistor RTr is turned on, the power voltage VDD may be electrically connected to the floating diffusion node FDN via the reset transistor RTr, and thus the floating diffusion node FDN may have a voltage equal to the power voltage VDD or slightly lower or higher than the power voltage VDD. In the discussion that follows, the state in which the floating diffusion node FDN has a voltage equal to the power voltage VDD or slightly lower or higher than the power voltage VDD is referred to as the “reset state.”

The signal output unit 302 may output a voltage signal corresponding to the voltage of the floating diffusion node FDN in response to the select control signal SC. This may be carried out by the source follower FTr of the signal output unit 302. The select transistor STr may transfer the voltage signal output from the source follower FTr to the output node Nout of the pixel circuit in response to the select control signal SC.

In FIG. 3, the source follower FTr may be an N-type MOSFET including a gate connected to the floating diffusion node FDN, a first terminal connected to the source of the power voltage VDD, and/or a second terminal connected to the select transistor STr. The select transistor STr may be an N-type MOSFET including a gate receiving the select control signal SC, a first terminal connected to the source follower FTr, and/or a second terminal connected to the output node Nout of the pixel circuit.

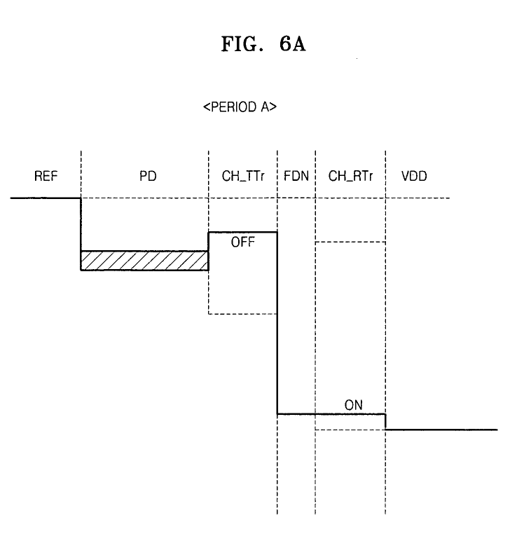

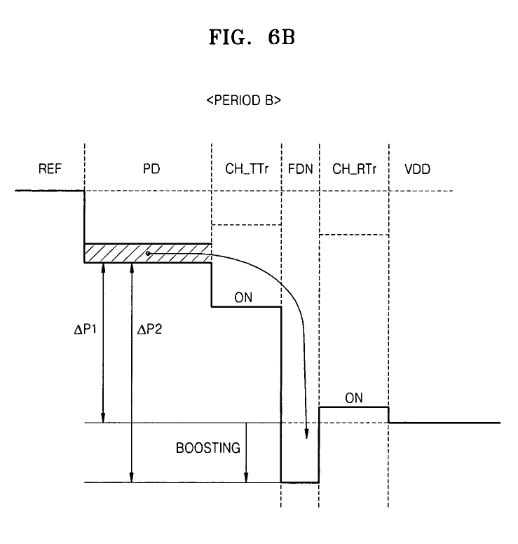

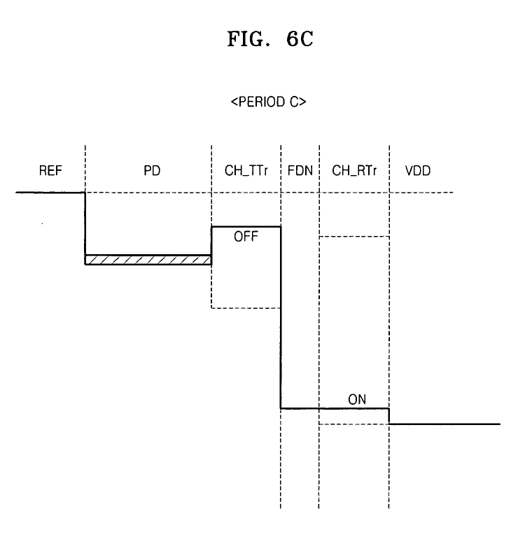

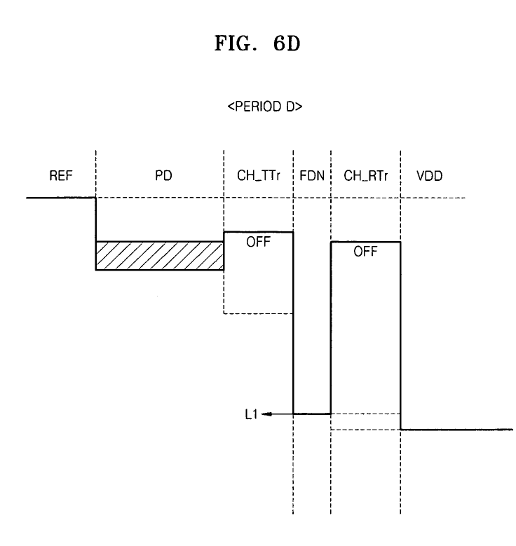

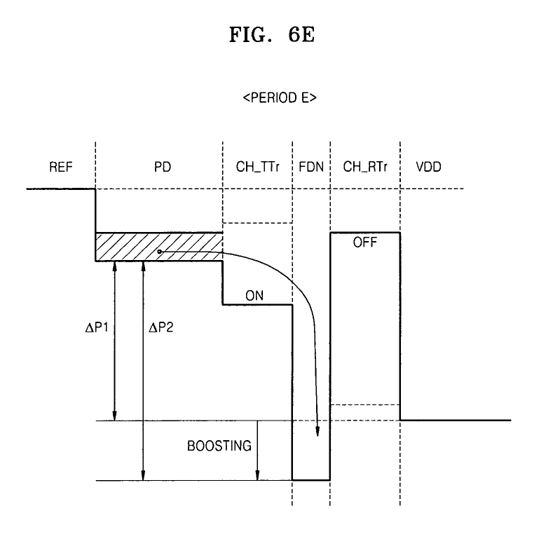

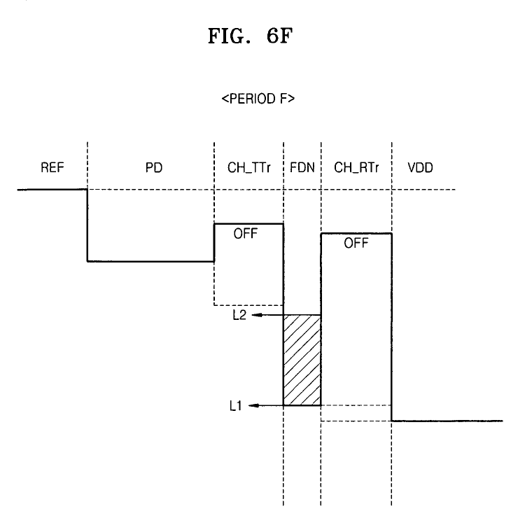

The boosting capacitor Cb may be connected between the gate of the transfer transistor TTr and the floating diffusion node FDN. The operation of the boosting capacitor Cb will be explained later in detail with reference to FIGS. 6B, 6C, 6D, and 6E. The boosting capacitor Cb may represent more than one capacitor connected in series, parallel, a combination of series and parallel, or in some other way.

The signal converter 304 may receive and sample the voltage signal Vout output from the output node Nout and/or may output a digital image signal S corresponding to the sampled result.

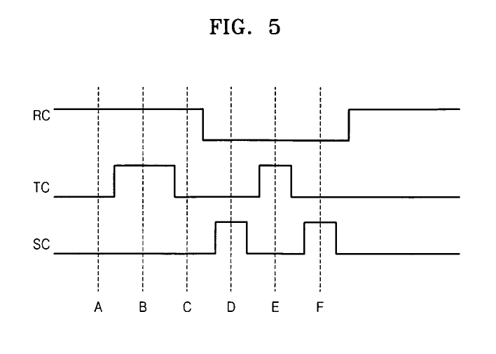

Example embodiments of a shutter operation of the pixel circuit of FIG. 3 will now be explained. FIG. 4 is a diagram for explaining the example embodiment. In FIG. 4, the horizontal axis represents time and the vertical axis represents quantity of photocharges generated by the photodiode PD.

The photodiode PD may have a saturation level, as shown in FIG. 4, due to its physical characteristics. As illustrated in FIG. 4, the quantity of photocharges generated by the photodiode PD does not reach the saturation level during a unit detection time Tt in the pixel circuit when a weak light is input to the photodiode PD (Q in FIG. 4). When an intense light is input to the photodiode PD (P in FIG. 4), however, the quantity of photocharges generated by the photodiode PD reaches the saturation level during the unit detection time Tt in the pixel circuit.

When the transfer transistor TTr is turned on in a case in which the quantity of photocharges generated by the photodiode PD reaches the saturation level during the unit detection time Tt, the floating diffusion node FDN in the reset state may have a voltage corresponding to the saturation level of the photodiode PD. In this case, the signal output unit 302 may output a voltage signal Vout corresponding to the saturation level, not the voltage signal Vout corresponding to the light Lin input to the photodiode PD. Consequently, an image sensor including the pixel circuit may not output a correct digital image signal S corresponding to the light Lin input to the photodiode PD.

The shutter operation of the pixel circuit solves this problem. That is, the transfer transistor TTr and the reset transistor RTr may be turned on during a shutter operation period Ts so that the photocharges generated by the photodiode PD may be transferred to the source of the power voltage VDD via the transfer transistor TTr and the reset transistor RTr when a very intense light Lin is input to the photodiode PD. Then, the image sensor may output a digital image signal S corresponding to the saturation level of the photodiode PD. Consequently, the photodiode PD may maintain an initialization state during the shutter operation period Ts. When the shutter operation period Ts is complete (for example, when the transfer transistor TTr is turned off), photocharges may be newly integrated in the photodiode PD from the time when the shutter operation period Ts is complete.

In FIG. 4, R represents a possible shutter operation period Ts when an intense light is input to the photodiode PD.

The shutter operation period Ts in the pixel circuit may be controlled by an image signal processor. The image signal processor may control the shutter operation period Ts in consideration of the intensity of light input to the photodiode PD and/or the saturation level of the photodiode PD.

Operation of the pixel circuit of FIG. 3 will now be explained with reference to FIGS. 5 and 6A through 6F. FIG. 5 is a timing diagram of control signals for driving the pixel circuit according to an example embodiment. FIG. 5 illustrates a reset control signal RC, a transfer control signal TC, and a select control signal SC for periods A, B, C, D, E, and F. FIGS. 6A through 6F illustrate potential levels of nodes and channel regions of the pixel circuit of FIG. 3. FIGS. 6A through 6F, respectively, correspond to the periods A, B, C, D, E, and F of FIG. 5.

FIGS. 6A through 6F illustrate the potential levels of the reference voltage REF, a region of the photodiode PD, a channel region CH_TTr of the transfer transistor TTr, a region of the floating diffusion node FDN, a channel region CH_RTr of the reset transistor RTr, and/or the power voltage VDD. As illustrated in FIGS. 6A through 6F, the potential level of the channel region CH_TTr of the transfer transistor TTr may vary in response to the logic level of the transfer control signal TC and the potential level of the channel region CH_RTr of the reset transistor RTr may vary in response to the logic level of the reset control signal RC.

Referring to FIG. 6A, the transfer transistor TTr may be turned off and the reset transistor RTr may be turned on, and thus the floating diffusion node FDN becomes or remains in a reset state in the period A. In the period A, the power voltage VDD may be applied to one terminal of the boosting capacitor Cb and the transfer control signal TC at a low level may be applied to the other terminal of the boosting capacitor Cb because the reset transistor RTr may be turned on. Accordingly, the boosting capacitor Cb may be charged with a voltage corresponding to a difference between the power voltage VDD and the voltage of the transfer control signal TC at the low level.

Referring to FIG. 6B, the period B corresponds to the shutter operation period Ts of FIG. 4. In the period B, the transfer transistor TTr and the reset transistor RTr may be turned on to maintain the photodiode PD in an initialization state during the shutter operation period Ts. As described above, the shutter operation period Ts may be controlled in consideration of the intensity of light input to the photodiode PD and/or the saturation level of the photodiode PD.

In the period B, the boosting capacitor Cb boosts the voltage of the floating diffusion node FDN to a voltage higher than the power voltage VDD, at the time when the transfer transistor TTr may be turned on, using the charges stored in the boosting capacitor Cb in the period A.

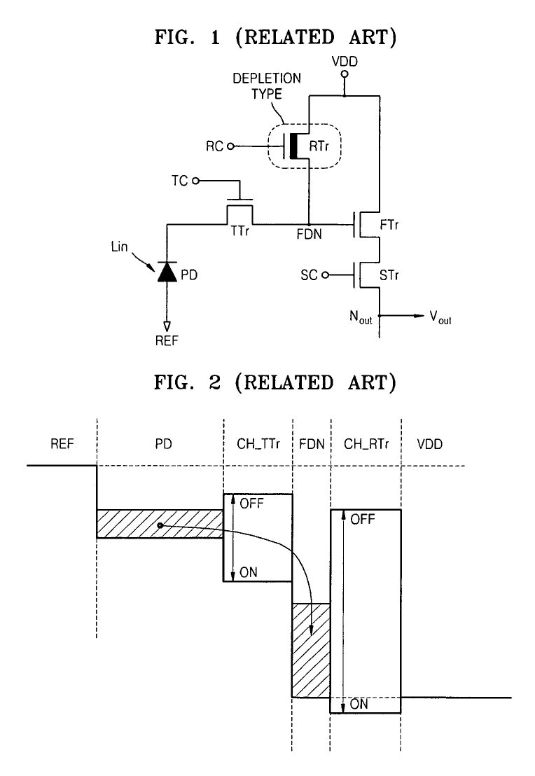

In the period B, the floating diffusion node FDN having a voltage higher than the power voltage VDD because of the voltage boost of the boosting capacitor Cb may draw photocharges generated by the photodiode PD more strongly. When the pixel circuit does not include such a boosting capacitor (refer to FIG. 1), a difference between the potential levels of the region of the photodiode PD and the region of the floating diffusion node FDN may correspond to AP1. When the pixel circuit includes the boosting capacitor Cb, the difference between the potential levels of the region of the photodiode PD and the region of the floating diffusion node FDN may be increased to ΔP2, as illustrated in FIG. 6B. That is, ΔP2 may be greater than ΔP1 by the voltage boost of the boosting capacitor Cb. Consequently, a rate of transferring photocharges from the photodiode PD to the floating diffusion node FDN may be increased when the pixel circuit includes the boosting capacitor Cb over the related art pixel circuit that does not include a boosting capacitor. A degree of voltage boos may be determined by the capacitance of the boosting capacitor Cb. For example, the voltage-boost effect lasts longer as the capacitance of the boosting capacitor Cb becomes larger.

In the present invention, a capacitor having a MIM structure or a capacitor having a PIP structure may be used as the boosting capacitor Cb. If the boosting capacitor Cb represents more than one capacitor, at least one of the capacitors may have a MIM structure. If the boosting capacitor Cb represents more than one capacitor, at least one of the capacitors may have a PIP structure.

Referring to FIG. 6C, the shutter operation may be ended by turning off the transfer transistor TTr in the period C. In the period C, photocharges may start to be newly integrated in the photodiode PD from the time when the shutter operation is complete. When the transfer transistor TTr may be turned off, the boosting may be ended and thus the floating diffusion node FDN may become a reset state. In the period C, the boosting capacitor Cb may be charged with a voltage corresponding to a difference between the power voltage VDD and the voltage of the transfer control signal TC at a low level, which may be similar to the operation in the period A.

Referring to FIG. 6D, the select transistor STr may be turned on, and thus the signal output unit 302 may output a voltage signal corresponding to the voltage of the floating diffusion node FDN in the reset state in the period D. In FIG. 6D, L1 represents the voltage of the floating diffusion node FDN in the reset state.

Referring to FIG. 6E, the reset transistor RTr may be turned off and the transfer transistor may be turned on and, thus, at least some of the photocharges integrated in the photodiode PD may be transferred to the floating diffusion node FDN in the reset state in the period E. In the period E, the boosting capacitor Cb boosts the voltage of the floating diffusion node FDN to a voltage higher than the power voltage VDD at the time when the transfer transistor TTr may be turned, on using the charges stored in the boosting capacitor Cb in the period C, which may be similar to the operation in the period B. The floating diffusion node FDN, having a voltage higher than the power voltage VDD due to the voltage boos of the boosting capacitor Cb, draws the photocharges integrated in the photodiode PD more strongly. Accordingly, the photocharge transfer rate may be improved due to the voltage boos of the boosting capacitor Cb.

Referring to FIG. 6F, when the period E may be ended by the turning off of the transfer transistor TTr, the voltage of the floating diffusion node FDN becomes a voltage (referred to as “image voltage”) corresponding to the light Lin input to the photodiode PD. Specifically, the floating diffusion node FDN may have a voltage L2 according to an inflow of photocharges from the photodiode PD and the completion of the boosting due to the turning off of the transfer transistor TTr. In FIG. 6F, L2 represents the image voltage of the floating diffusion node FDN and L1 represents the voltage of the floating diffusion node FDN in the reset state.

In the period F, the transfer transistor TTr and the reset transistor RTr may be turned off and the select transistor STr may be turned on and, thus, the signal output unit 302 may output a voltage signal corresponding to the image voltage of the floating diffusion node FDN.

Example embodiments of a method of driving the pixel circuit will now be described. Specifically, a method of driving the pixel circuit according to the example embodiment is described in which the control signals have the control timings of FIG. 5.

First, the transfer transistor TTr and the reset transistor RTr may be turned on to maintain the photodiode PD in an initialization state during the shutter operation period Ts. This corresponds to the period B. Then, the transfer transistor TTr may be turned off and the reset transistor RTr may be turned on so that the floating diffusion node FDN becomes a reset state. This corresponds to the period C.

Subsequently, the select transistor may be turned on so that the signal output unit 302 may output a voltage signal corresponding to the voltage of the floating diffusion node FDN in the reset state. This corresponds to the period D. Then, the reset transistor RTr may be turned off and the transfer transistor TTr may be turned on so that the voltage of the floating diffusion node FDN may become the image voltage corresponding to the light Lin input to the photodiode PD. This corresponds to the period E.

The signal output unit 302 may output a voltage signal corresponding to the image voltage of the floating diffusion node FDN. This corresponds to the period F.

Example embodiments of the operation of the signal converter 304 in the periods A through F will now be explained.

The voltage signal (voltage signal output from the signal output unit 302 in the period D) corresponding to the voltage of the floating diffusion node FDN in the reset state and the voltage signal (voltage signal output from the signal output unit 302 in the period F) corresponding to the image voltage of the floating diffusion node FDN may be input to the signal converter 304. The signal converter 304 may compare the two voltage signals and may output a digital image signal S corresponding to the comparison result.

The signal converter 304 may include a comparator (not shown) for comparing the voltage signal corresponding to the voltage of the floating diffusion node FDN in the reset state to the voltage signal corresponding to the image voltage of the floating diffusion node FDN, an amplifier (not shown) for amplifying a signal, and/or an analog-digital converter (not shown) for converting an analog voltage signal into a digital image signal.

The signal converter 304 may process the voltage signal corresponding to the voltage of the floating diffusion node FDN in the reset state and the voltage signal corresponding to the image voltage of the floating diffusion node FDN using CDS to generate the comparison result. When CDS is used, the signal converter 304 subtracts the voltage signal corresponding to the image voltage of the floating diffusion node FDN from the voltage signal corresponding to the voltage of the floating diffusion node FDN in the reset state and outputs the digital image signal S corresponding to the subtraction result.

Using the aforementioned process, the image sensor including the pixel circuit may output the digital image signal S corresponding to the light Lin input to the photodiode PD.

In example embodiments, an enhancement type MOSFET may be used as the reset transistor RTr. In other example embodiments, a pixel circuit using a depletion type MOSFET may be used as the reset transistor RTr. A pixel circuit using a depletion type MOSFET as the reset transistor RTr will now be explained for comparison purposes.

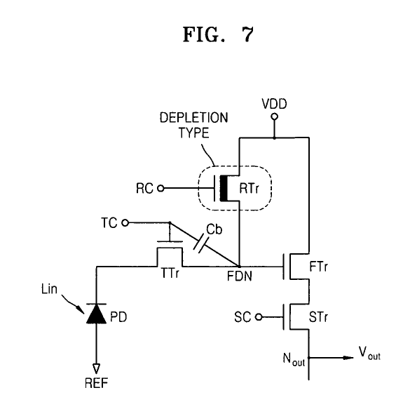

FIG. 7 is a circuit diagram of a pixel circuit of an image sensor according to example embodiments using a depletion type MOSFET as the reset transistor. The pixel circuit includes a photodiode PD receiving light Lin, a transfer transistor TTr that may receive a transfer control signal TC, a floating diffusion node FDN, a boosting capacitor Cb, a reset transistor RTr that may receive a reset control signal RC, a source follower FTr, a select transistor STr that may receive a select control signal SC, and/or an output node Nout.

As illustrated in FIG. 7, the reset transistor RTr may be a depletion type MOSFET. The operation of the pixel circuit will now be explained with reference to FIGS. 8A and 8B. FIGS. 8A and 8B illustrate potential levels of nodes and channel regions of the pixel circuit of FIG. 7 when the control signals of FIG. 5 may be applied to the pixel circuit of FIG. 7. FIG. 8A corresponds to the period E of FIG. 5 and FIG. 8B corresponds to the period B of FIG. 5.

In FIGS. 8A and 8B, the potential levels of the reference voltage REF, the region of the photodiode PD, a channel region CH_TTr of the transfer transistor TTr, the region of the floating diffusion node FDN, a channel region CH_RTr of the reset transistor RTr, and/or the power voltage VDD are illustrated.

When the control signals RC, TC, and SC of FIG. 5 may be applied to the pixel circuit of FIG. 7, the floating diffusion node FDN may become a reset state and the boosting capacitor Cb may be charged with a voltage corresponding to a difference between the power voltage VDD and the voltage of the transfer control signal at a low level in the period C. In the period D, the signal output unit 302 may output a voltage signal corresponding to the voltage of the floating diffusion node FDN in the reset state.

Referring to FIG. 8A, the reset transistor RTr may be turned off and the transfer transistor TTr may be turned on and, thus, photocharges integrated in the photodiode PD may be transferred to the floating diffusion node FDN in the reset state in the period E. Here, the boosting capacitor Cb boosts the voltage of the floating diffusion node FND to a voltage higher than the power voltage VDD, at the time when the transfer transistor TTr may be turned on, using the charges stored in the period C. The floating diffusion node FDN, having a voltage higher than the power voltage VDD due to the voltage boost of the boosting capacitor Cb, may draw the photocharges integrated in the photodiode PD more strongly.

Referring to FIG. 8B, the transfer transistor TTr and the reset transistor RTr may be turned on, and thus photocharges generated in the photodiode PD may be transferred to the source of the power voltage VDD via the transfer transistor TTr and the reset transistor RTr in the period B. As described above, the period B corresponds to the shutter operation period Ts.

However, in the period B of FIG. 8B, the voltage boost of the boosting capacitor Cb does not occur, as distinguished from the period B of FIG. 6B. This is because, with a depletion type MOSFET as the reset transistor, the potential level of the floating diffusion node FDN may be held at the potential level of the power voltage VDD.

In the period E of FIG. 6E and the period E of FIG. 8A, the reset transistor RTr may be turned off and, thus, the potential level of the floating diffusion node FDN may not be held at the potential level of the power voltage VDD. Accordingly, the voltage boost of the boosting capacitor Cb occurs. In the period B of FIG. 6B, in contrast to the period B of FIG. 8B, the voltage boost of the boosting capacitor Cb occurs. The reason will now be explained.

The potential level of the channel region CH_RTr of the reset transistor RTr may be lower than the potential level of the power voltage VDD when the reset transistor RTr is turned on, as illustrated in FIG. 6B, because the reset transistor RTr of FIG. 3 may be an enhancement type MOSFET (the potential level of the reference voltage REF may be lower than the potential level of the power voltage VDD, as shown in FIGS. 6A through 6F, 8A, and 8B). On the other hand, the potential level of the channel region CH_RTr of the reset transistor RTr may be higher than the potential level of the power voltage VDD when the reset transistor RTr is turned on, as illustrated in FIG. 8B, because the reset transistor RTr of FIG. 7 may be a depletion type MOSFET.

Accordingly, though the potential level of the floating diffusion node FDN may not be held at the potential level of the power voltage VDD even when the reset transistor RTr is turned on, the potential level of the floating diffusion node FDN may be held at the potential level of the power voltage VDD when the reset transistor RTr is turned on in FIG. 8B. Consequently, the voltage boost of the boosting capacitor Cb does not occur in the period B of FIG. 8B, in which the potential level of the floating diffusion node FDN may be held at the potential level of the power voltage VDD, while the voltage boost of the boosting capacitor Cb occurs in the period B of FIG. 6B, in which the potential level of the floating diffusion node FDN may not be held at the potential level of the power voltage VDD.

To solve the aforementioned problem, the pixel circuit according to the present invention may use an enhancement type MOSFET as the reset transistor RTr so that the voltage boost of the boosting capacitor Cb may be carried out in the period B of FIG. 5 as well as in the period E of FIG. 5.

While example embodiments have been particularly shown and described, it will be understood by those of ordinary skill in the art that various changes in form and details may be made therein without departing from the spirit and scope of the present invention as defined by the following claims.

What is claimed is:

1. A pixel circuit of an image sensor, comprising:
a photodiode that generates photocharges corresponding to light input to the photodiode;
a transfer transistor that transfers the photocharges to a floating diffusion node in response to a transfer control signal;
a reset transistor that transfers a power voltage to the floating diffusion node in response to a reset control signal;
a signal output unit that outputs a voltage signal corresponding to a voltage of the floating diffusion node in response to a select control signal; and
one or more boosting capacitors connected between a gate of the transfer transistor and the floating diffusion node;
wherein the reset transistor is an enhancement type MOSFET.

2. The pixel circuit of claim 1, wherein the reset transistor is an N-type MOSFET comprising a gate that receives the reset control signal, a first terminal connected to a source of the power voltage, and a second terminal connected to the floating diffusion node.

3. The pixel circuit of claim 1, wherein the one or more boosting capacitors boost the voltage of the floating diffusion node to a voltage higher than the power voltage, at a time when the transfer transistor is turned on, using charges previously stored in the one or more boosting capacitors.

4. The pixel circuit of claim 3, wherein if the one or more boosting capacitors is a single capacitor, a degree of the voltage boost is determined by the capacitance of the single capacitor, and
wherein if the one or more boosting capacitors is at least two capacitors, the degree of voltage boost is determined by the equivalent capacitance of the at least two capacitors.

5. The pixel circuit of claim 1, wherein at least one of the one or more boosting capacitors has a metal insulator metal (MIM) structure.

6. The pixel circuit of claim 1, wherein at least one of the one or more boosting capacitors has a polysilicon insulator polysilicon (PIP) structure.

7. The pixel circuit of claim 1, wherein the transfer transistor is an N-type MOSFET comprising a gate that receives the transfer control signal, a first terminal connected to the floating diffusion node, and a second terminal connected to the photodiode.

8. The pixel circuit of claim 1, wherein the signal output unit comprises:
a source follower that outputs a voltage signal corresponding to the voltage of the floating diffusion node; and
a select transistor that transfers the voltage signal output from the source follower to an output node of the pixel circuit in response to the select control signal.

9. The pixel circuit of claim 8, wherein the source follower is an N-type MOSFET comprising a gate connected to the floating diffusion node, a first terminal connected to a source of the power voltage, and a second terminal connected to the select transistor.

10. The pixel circuit of claim 8, wherein the select transistor is an N-type MOSFET comprising a gate that receives the select control signal, a first terminal connected to the source follower, and a second terminal connected to the output node.

11. The pixel circuit of claim 1, wherein the image sensor is a CMOS image sensor.

12. A method of driving a pixel circuit that comprises a transfer transistor connecting a photodiode and a floating diffusion node to each other or disconnecting the photodiode and the floating diffusion node from each other, a reset transistor that is an enhancement type MOSFET and that transfers a power voltage to the floating diffusion node, a signal output unit that outputs a voltage signal corresponding to a voltage of the floating diffusion node, and one or more boosting capacitors connected between a gate of the transfer transistor and the floating diffusion node, the method comprising:
turning on the transfer transistor and the reset transistor to maintain the photodiode in an initialization state during a shutter operation period;
turning off the transfer transistor and turning on the reset transistor so that the floating diffusion node becomes a reset state;
outputting a voltage signal corresponding to the voltage of the floating diffusion node in the reset state;
turning off the reset transistor and turning on the transfer transistor so that the voltage of the floating diffusion node becomes an image voltage corresponding to light input to the photodiode; and
outputting a voltage signal corresponding to the image voltage of the floating diffusion node.

13. The method of claim 12, wherein in the turning on of the transfer transistor and the reset transistor to maintain the photodiode in an initialization state during a shutter operation period, the one or more boosting capacitors boost the voltage of the floating diffusion node to a voltage higher than the power voltage at a time when the transfer transistor is turned on using charges previously stored in the one or more boosting capacitors.

14. The method of claim 13, further comprising turning off the transfer transistor and turning on the reset transistor so that the floating diffusion node becomes a reset state before the turning on of the transfer transistor and the reset transistor to maintain the photodiode in an initialization state during a shutter operation period.

15. The method of claim 14, wherein in the turning on of the transfer transistor and the reset transistor to maintain the photodiode in an initialization state during a shutter operation period, the one or more boosting capacitors boost the voltage of the floating diffusion node to a voltage higher than the power voltage using charges stored in the turning off of the transfer transistor and turning on of the reset transistor so that the floating diffusion node becomes a reset state.

16. The method of claim 12, wherein in the turning off of the reset transistor and turning on of the transfer transistor so that the voltage of the floating diffusion node becomes an image voltage corresponding to light input to the photodiode, the one or more boosting capacitors boost the voltage of the floating diffusion node to a voltage higher than the power voltage at a time when the transfer transistor is turned on using charges previously stored in the one or more boosting capacitors.

17. The method of claim 16, wherein in the turning off of the reset transistor and turning on of the transfer transistor so that the voltage of the floating diffusion node becomes an image voltage corresponding to light input to the photodiode, the one or more boosting capacitors boost the voltage of the floating diffusion node to a voltage higher than the power voltage using charges stored in the turning off of the transfer transistor and turning on of the reset transistor so that the floating diffusion node becomes reset state.

18. The method of claim 12, wherein in the turning on of the transfer transistor and the reset transistor to maintain the photodiode in an initialization state during a shutter operation period, the shutter operation period is controlled in consideration of an intensity of light input to the photodiode, a saturation level of the photodiode, or the intensity of light input to the photodiode and the saturation level of the photodiode.

19. The method of claim 12, wherein in the turning off of the reset transistor and turning on of the transfer transistor so that the voltage of the floating diffusion node becomes an image voltage corresponding to light input to the photodiode, the voltage of the floating diffusion node becomes the image voltage due to transfer of photocharges, generated in the photodiode that correspond to light input to the photodiode, to the floating diffusion node via the transfer transistor.

20. An image sensor, comprising:
a transfer transistor that connects a photodiode and a floating diffusion node to each other in response to a transfer control signal or that disconnects the photodiode and the floating diffusion node from each other in response to the transfer control signal;
a reset transistor that transfers a power voltage to the floating diffusion node in response to a reset control signal;
one or more boosting capacitors connected between a gate of the transfer transistor and the floating diffusion node, the one or more boosting capacitors boosting a voltage of the floating diffusion node to a voltage higher than the power voltage at a time when the transfer transistor is turned on;
a signal output unit that outputs a voltage signal corresponding to the voltage of the floating diffusion node in response to a select control signal; and
a signal converter that receives and samples the voltage signal and that outputs a digital image signal;
wherein the reset transistor is an enhancement type MOSFET.

21. The image sensor of claim 20, wherein the one or more boosting capacitors boost the voltage of the floating diffusion node to a voltage higher than the power voltage at the time when the transfer transistor is turned on using charges stored when the reset transistor is turned on so that the floating diffusion node becomes a reset state.

22. The image sensor of claim 20, wherein at least one of the one or more boosting capacitors has an MIM structure.

23. The image sensor of claim 20, wherein at least one of the one or more boosting capacitors has a PIP structure.

24. The image sensor of claim 20, wherein the signal output unit comprises:
a source follower that outputs a voltage signal corresponding to the voltage of the floating diffusion node; and
a select transistor that transfers the voltage signal output from the source follower to the signal converter in response to the select control signal.

25. The image sensor of claim 24, wherein the transfer transistor is an N-type MOSFET,
wherein the reset transistor is an N-type MOSFET,
wherein the source follower is an N-type MOSFET, or
wherein the select transistor is an N-type MOSFET.

26. The image sensor of claim 24, wherein the transfer transistor is an N-type MOSFET,
wherein the reset transistor is an N-type MOSFET,
wherein the source follower is an N-type MOSFET, and
wherein the select transistor is an N-type MOSFET.

27. The image sensor of claim 20, wherein the voltage of the floating diffusion node has a potential level of a reset state when the transfer transistor is turned off and the reset transistor is turned on.

28. The image sensor of claim 27, wherein the floating diffusion node has an image voltage corresponding to light input to the photodiode when the transfer transistor is turned on and the reset transistor is turned off.

29. The image sensor of claim 28, wherein the signal converter compares a voltage signal corresponding to the potential level of the reset state to a voltage signal corresponding to an image voltage and outputs the digital image signal on a basis of a result of the comparison.

30. The image sensor of claim 29, wherein the result of the comparison is obtained by processing the voltage signal corresponding to the potential level of the reset state and the voltage signal corresponding to the image voltage using correlated double sampling.

31. The image sensor of claim 20, wherein the image sensor is a CMOS image sensor.
